(19) United States
(12) Patent Application Publication
(10) Pub. No.: US 2024/0200196 A1
(43) Pub. Date: Jun. 20, 2024

(54) CATALYST APPLICATION BATH FOR ELECTROLESS PLATING, METHOD OF PRODUCING CATALYTIC NUCLEUS-CONTAINING MATERIAL TO BE ELECTROLESS PLATED, METHOD OF PRODUCING MATERIAL WITH ELECTROLESS PLATING DEPOSIT, AND MATERIAL WITH ELECTROLESS PLATING DEPOSIT

(71) Applicant: C.Uyemura & Co., Ltd., Osaka (JP)

(72) Inventors: Naoki Nakano, Osaka (JP); Mai Odajima, Osaka (JP); Tsuyoshi Maeda, Osaka (JP); Katsuhisa Tanabe, Osaka (JP)

(73) Assignee: C.Uyemura & Co., Ltd., Osaka (JP)

(21) Appl. No.: 18/390,421

(22) Filed: Dec. 20, 2023

(30) Foreign Application Priority Data
Dec. 20, 2022 (JP) 2022-203430

(51) Int. Cl. C23C 18/54

(52) U.S. Cl. CPC C23C 18/54

(57) ABSTRACT

Provided are a catalyst application bath for electroless plating, a method of producing a catalytic nucleus-containing material to be electroless plated using the catalyst application bath for electroless plating, a method of producing a material with an electroless plating deposit, and a material with an electroless plating deposit, each of which may provide good patternability even without a post-dip step which can cause non-deposition in electroless plating, and thus may achieve both patternability and electroless plating deposition. Included is a catalyst application bath for electroless plating, containing a palladium compound and an aminocarboxylic acid.

### TECHNICAL FIELD

The present invention relates to a catalyst application bath for electroless plating, a method of producing a catalytic nucleus-containing material to be electroless plated, a method of producing a material with an electroless plating deposit, and a material with an electroless plating deposit.

### BACKGROUND ART

As electronic devices have become smaller and denser, the copper trace patterns and spaces on the printed circuit boards and package substrates (hereinafter, also referred to simply as substrates) used in these devices have become increasingly fine.

### SUMMARY OF INVENTION

### Technical Problem

Extensive studies of the present inventors have revealed the following.

Electroless plating on fine copper traces requires high patternability because even minor out-of-pattern deposition can easily cause connection between the traces, resulting in a short circuit.

When performing electroless plating of nickel, palladium, etc., on copper traces, a catalyst application step (activator step) is necessary. Thus, techniques of applying a palladium catalyst have been widely used. In such an activator step, the palladium catalyst may remain between the traces, causing out-of-pattern deposition during the subsequent electroless plating step.

A post-dip step is performed after the activator step to suppress electroless plating deposition in the spaces between the traces. There are two types of post-dip processes, one of which has an effect of removing the remaining catalyst, and the other of which has an effect of adsorbing to the remaining catalyst for deactivation. Both of these effects often affect the catalyst applied to the copper trace patterns as well. This can inhibit electroless plating on the copper trace patterns, resulting in non-deposition.

As a result of extensive studies, the present inventors have further revealed the following.

### (1) Patternability Problem

When a conventional activator is used on a substrate with fine traces and spaces between the traces, a catalyst can disadvantageously be applied to unexpected parts, resulting in electroless plating deposition on such unintended parts. In electroless plating on fine copper traces, even minor out-of-pattern deposition can easily cause connection between the traces, resulting in a short circuit.

The following can be considered as the cause of the patternability problem.
(a) The substrate with a chemical solution adhered thereto in the activator step is subjected to the subsequent step of washing with water.
(b) Once the substrate is allowed to contact an acidic chemical solution and then neutral ion-exchange water, the palladium may change its state from ionic to unstable. Moreover, in narrow spaces between the traces (outside the patterns), it cannot be completely washed off with water.
(c) Upon contact with an electroless plating bath, the unstable palladium remaining outside the patterns may act as a reaction starting point, causing out-of-pattern deposition.

### (2) Post-Dip Problem

The use of a conventional activator requires a subsequent post-dip step to remove the remaining catalyst and to adsorb to the remaining catalyst for deactivation. The removal and deactivation of the remaining catalyst often affect the catalyst applied within the traces, possibly resulting in non-deposition in plating. The impact of this problem becomes greater than in the past as the substrates, traces, and spaces become finer.

As described above, the conventional techniques combining an activator with a post-dip step have been found to have more difficulty in achieving both patternability and electroless plating deposition as the copper trace patterns and spaces in the substrates have become finer.

The present invention aims to solve the problem newly found by the present inventors and provide a catalyst application bath for electroless plating, a method of producing a catalytic nucleus-containing material to be electroless plated using the catalyst application bath for electroless plating, a method of producing a material with an electroless plating deposit, and a material with an electroless plating deposit, each of which may provide good patternability even without a post-dip step which can cause non-deposition in electroless plating, and thus may achieve both patternability and electroless plating deposition.

### Solution to Problem

As a result of extensive studies, the present inventors have found that the use of a catalyst application bath for electroless plating having a specific composition may provide good patternability even without a post-dip step which can cause non-deposition in electroless plating, and thus may achieve both patternability and electroless plating deposition. This finding has led to the completion of the present invention.

Specifically, exemplary embodiments of the present invention include:

Embodiment 1. A catalyst application bath for electroless plating, containing at least one palladium compound and at least one aminocarboxylic acid.

Embodiment 2. The catalyst application bath for electroless plating according to Embodiment 1,

wherein the catalyst application bath contains the palladium compound in an amount corresponding to a palladium concentration of 1 to 1000 mg/L.

Embodiment 3. The catalyst application bath for electroless plating according to Embodiment 1 or 2,

wherein the catalyst application bath contains the aminocarboxylic acid in an amount of 0.2 to 20 g/L.

Embodiment 4. The catalyst application bath for electroless plating according to any one of Embodiments 1 to 3,

wherein the catalyst application bath contains an inorganic acid.

Embodiment 5. The catalyst application bath for electroless plating according to any one of Embodiments 1 to 4,

wherein the catalyst application bath has a pH of 6.5 or less.

Embodiment 6. The catalyst application bath for electroless plating according to any one of Embodiments 1 to 5,

wherein the electroless plating is for a material having a surface on which at least one of copper or a copper alloy is exposed.

Embodiment 7. A method of producing a catalytic nucleus-containing material to be electroless plated, the method including

catalyst application including allowing a material to be electroless plated to contact the catalyst application bath for electroless plating according to any one of Embodiments 1 to 6.

Embodiment 8. A method of producing a material with an electroless plating deposit, the method including:

catalyst application including allowing a material to be electroless plated to contact the catalyst application bath for electroless plating according to any one of Embodiments 1 to 6; and

electroless plating after the catalyst application.

Embodiment 9. A material, including: a material having a surface on which a metal is exposed;

a catalytic nucleus on the metal; and

a deposit on the catalytic nucleus,

the catalytic nucleus containing palladium,

the deposit being an electroless plating deposit.

### Advantageous Effects of Invention

The catalyst application bath for electroless plating according to the present invention contains a palladium compound and an aminocarboxylic acid. This catalyst application bath may provide good patternability even without a post-dip step which can cause non-deposition in electroless plating, and thus may achieve both patternability and electroless plating deposition.

### DESCRIPTION OF EMBODIMENTS

The catalyst application bath for electroless plating (catalyst application solution for electroless plating) of the present invention contains a palladium compound and an aminocarboxylic acid. Thus, the catalyst application bath may provide good patternability even without a post-dip step which can cause non-deposition in electroless plating, and thus may achieve both patternability and electroless plating deposition.

The catalyst application bath for electroless plating provides the above-described effect probably for the following reasons.

### (1) Solution to Patternability Problem

(a) The aminocarboxylic acid added as a complexing agent to the catalyst application bath for electroless plating (activator bath) of the present invention may form a complex with the palladium (metal applied as catalyst) in the activator.
(b) The palladium forming the complex is less unstable in a water washing step and is easier to wash off during the water washing step.
(c) Thus, it is believed that the palladium outside the traces can be easily removed to reduce the reaction starting points of electroless plating outside the traces, resulting in improved patternability.
(d) The palladium on the copper traces is present in the form of metallic palladium due to a substitution reaction and cannot be washed off with water. It is therefore possible to remove only the palladium outside the traces.

Accordingly, the catalyst application bath for electroless plating of the present invention provides good patternability.

### (2) Solution to Post-Dip Problem (Electroless Plating Deposition)

As described in the above (1), the unnecessary palladium outside the traces can be removed only by water washing, eliminating the need for a conventional post-dip step. As a result, the post-dip step-related problem, i.e., the possibility of non-deposition in electroless plating, is eliminated, resulting in good electroless plating deposition.

Accordingly, due to the synergistic effect of the palladium compound and the aminocarboxylic acid, the catalyst application bath for electroless plating of the present invention may provide good patternability even without a post-dip step which can cause non-deposition in electroless plating, and thus may achieve both patternability and electroless plating deposition.

A catalytic nucleus-containing material to be electroless plated can be produced by subjecting a material to be electroless plated to catalyst application using the catalyst application bath for electroless plating of the present invention. This catalytic nucleus-containing material to be electroless plated has only a few reaction starting points of electroless plating outside the traces but has palladium as a catalytic nucleus serving as a reaction starting point on the traces, as described above. Thus, it is excellent in both patternability and electroless plating deposition. Then, when the catalytic nucleus-containing material to be electroless plated is subjected to electroless plating, the electroless plating may proceed while suppressing out-of-pattern deposition to produce a material with an electroless plating deposit. This material with an electroless plating deposit is excellent in both patternability and electroless plating deposition. Thus, it can be suitably used in printed wiring boards and package substrates with finer copper trace patterns and/or spaces and in smaller and denser electronic devices.

### Catalyst Application Bath for Electroless Plating

The catalyst application bath for electroless plating of the present invention contains at least one palladium compound and at least one aminocarboxylic acid.

### Palladium Compound

The palladium compound may be deposited on traces to form a catalytic nucleus which serves as a reaction starting point of electroless plating.

Any palladium compound which is soluble in the catalyst application bath for electroless plating may be used. Specific examples include inorganic and organic palladium salts, such as palladium chloride, palladium sulfate, palladium nitrate, palladium acetate, palladium bromide, palladium iodide, tetraamine palladium hydrochloride, tetraamine palladium sulfate, and dinitrodiammine palladium. These may be used alone or in combinations of two or more. Palladium chloride or palladium sulfate is preferred among these.

The catalyst application bath for electroless plating preferably contains the palladium compound in an amount corresponding to a palladium (metallic palladium (Pd)) concentration of 1 to 1000 mg/L, more preferably 3 to 200 mg/L, still more preferably 5 to 100 mg/L, particularly preferably 10 to 100 mg/L. When the amount is within the range indicated above, both patternability and electroless plating deposition tend to be better achieved.

The amount of metal compounds other than the palladium compound, calculated as the metal concentration, in the catalyst application bath for electroless plating is preferably not more than 0.1 mg/L, more preferably not more than 0.05 mg/L, still more preferably not more than 0.01 mg/L. In such cases, the advantageous effect of the present invention tends to be better achieved.

Here, when the catalyst application bath contains a plurality of metals other than palladium, the metal concentration refers to the total concentration. The same applies to the concentrations of other components.

The palladium content based on 100% by mass of the metal content in the catalyst application bath for electroless plating is preferably 80% by mass or higher, more preferably 90% by mass or higher, still more preferably 95% by mass or higher, particularly preferably 98% by mass or higher, and may be 100% by mass. In such cases, both patternability and electroless plating deposition tend to be better achieved.

### Aminocarboxylic Acid

The aminocarboxylic acid may form a complex with palladium. Specifically, the aminocarboxylic acid functions as a complexing agent. The aminocarboxylic acid may be in the L-form, D-form, or DL-form, preferably L-form. The aminocarboxylic acid may be a single compound or a combination of two or more compounds. Herein, the aminocarboxylic acid refers to a compound containing an amino group and a carboxyl group, i.e., an amino acid, and may also be a derivative in which the amino group and/or carboxylic group is derivatized. Obviously, the amino group and/or carboxylic group may form a part of a ring.

The aminocarboxylic acid may be any aminocarboxylic acid capable of forming a complex with palladium. Studies of the present inventors have revealed that particularly when (1) a sulfur atom-containing aminocarboxylic acid or a derivative thereof or (2) a less hydrophobic aminocarboxylic acid or a derivative thereof is used, both patternability and electroless plating deposition tend to be better achieved. Therefore, the aminocarboxylic acid is preferably (1) a sulfur atom-containing aminocarboxylic acid or a derivative thereof or (2) a less hydrophobic aminocarboxylic acid or a derivative thereof.

Examples of the sulfur atom-containing aminocarboxylic acid or derivative thereof include methionine, cysteine, and derivatives thereof. Among the derivatives, alkylated or acetylated forms such as methylated or ethylated forms are preferred.

The less hydrophobic aminocarboxylic acid or derivative thereof is preferably an aminocarboxylic acid or derivative thereof which is less hydrophobic (more hydrophilic) than glycine as reference. Specific examples include serine, glutamine, aspartic acid, arginine, lysine, asparagine, histidine, proline, and derivatives thereof. Preferred among these are glutamine, histidine, aspartic acid, proline, and derivatives thereof, with histidine, aspartic acid, proline, and derivatives thereof being more preferred, with histidine, proline, and derivatives thereof being still more preferred. Among the derivatives, alkylated or acetylated forms are preferred.

The hydrophobicity of the aminocarboxylic acid can be calculated as described in Sereda et al, J. Chrom., 676: 139-53, 1994. Table 1 shows the hydrophobicity indices of 20 amino acids calculated as described in Sereda et al, J. Chrom., 676: 139-53, 1994. Herein, the term “hydrophobicity index” refers to a relative index of hydrophobicity that indicates how soluble an aminocarboxylic acid is in water. The values in Table 1 are measured at pH 2 and are relative to that of glycine taken as 0 and those of leucine and isoleucine, which are the most hydrophobic, each taken as 100. Negative values are given for aminocarboxylic acids that are more hydrophilic than glycine.

TABLE 1

| Aminocarboxylic acid | Leucine | Isoleucine | Phenylalanine | Tryptophan | Valine | Methionine | Cysteine |
|---|---|---|---|---|---|---|---|
| Hydrophobicity | 100 | 100 | 92 | 84 | 79 | 74 | 52 |

| Aminocarboxylic acid | Tyrosine | Alanine | Threonine | Glutamic acid | Glycine | Serine | Glutamine |
|---|---|---|---|---|---|---|---|
| Hydrophobicity | 49 | 47 | 13 | 8 | 0 | −7 | −18 |

| Aminocarboxylic acid | Aspartic acid | Arginine | Lysine | Asparagine | Histidine | Proline |
|---|---|---|---|---|---|---|
| Hydrophobicity | −18 | −26 | −37 | −41 | −42 | −46 |

The hydrophobicity (the hydrophobicity index defined above) of the aminocarboxylic acid (including the derivative of the aminocarboxylic acid) calculated as described in Sereda et al, J. Chrom., 676: 139-53, 1994 is preferably −1 or lower, preferably −5 or lower, more preferably −10 or lower, still more preferably −15 or lower. The lower limit is not limited and is preferably −50 or higher. When the hydrophobicity is within the range indicated above, both patternability and electroless plating deposition tend to be better achieved.

The catalyst application bath for electroless plating preferably contains the aminocarboxylic acid in an amount of 0.2 to 20 g/L, more preferably 0.5 to 15 g/L, still more preferably 0.8 to 10 g/L. When the amount is within the range indicated above, the aminocarboxylic acid and palladium may more properly form a complex, so that both patternability and electroless plating deposition tend to be better achieved.

The aminocarboxylic acid content based on 100% by mass of the complexing agent content in the catalyst application bath for electroless plating is preferably 80% by mass or higher, more preferably 90% by mass or higher, still more preferably 95% by mass or higher, particularly preferably 98% by mass or higher, and may be 100% by mass. In such cases, both patternability and electroless plating deposition tend to be better achieved.

In the catalyst application bath for electroless plating, the ratio of the aminocarboxylic acid concentration to the palladium (metallic palladium (Pd)) concentration (aminocarboxylic acid concentration (g/L)/Pd concentration (g/L)) is preferably 10 to 1000, more preferably 20 to 500, still more preferably 50 to 200. When the ratio is within the range indicated above, the aminocarboxylic acid and palladium may more properly form a complex, so that both patternability and electroless plating deposition tend to be better achieved.

Herein, the concentrations of metals such as the palladium (metallic palladium (Pd)) concentration in the catalyst application bath for electroless plating are measured using an ICP spectrometer (HORIBA).

Also, herein, the aminocarboxylic acid concentration in the catalyst application bath for electroless plating is measured using a liquid chromatograph (Shimadzu Corporation).

### pH

The pH of the catalyst application bath for electroless plating is preferably 6.5 or less, more preferably 5.5 or less, still more preferably 4.5 or less, particularly preferably 3.5 or less, most preferably 2.5 or less, even most preferably 1.5 or less, further most preferably 1.0 or less. The lower limit is not limited. When the pH is 6.5 or less, the aminocarboxylic acid and palladium may more properly form a complex, so that both patternability and electroless plating deposition tend to be better achieved.

Herein, the pH of the catalyst application bath for electroless plating is measured at 25° C.

The pH of the catalyst application bath for electroless plating may be adjusted by selecting the types of the palladium compound and the aminocarboxylic acid. Alkaline or acid components may optionally be added.

Non-limiting examples of the alkaline components include sodium hydroxide and ammonium. Non-limiting examples of the acid components include sulfuric acid and phosphoric acid. These alkaline or acid components may be used alone or in combinations of two or more. Inorganic acids are preferred among these.

Examples of the inorganic acids include sulfuric acid, hydrochloric acid, nitric acid, carbonic acid, and phosphoric acid. Sulfuric acid or hydrochloric acid is preferred among these.

The catalyst application bath for electroless plating preferably contains at least one inorganic acid in an amount of 1 to 200 g/L, more preferably 5 to 150 g/L, still more preferably 10 to 100 g/L. When the amount is within the range indicated above, the aminocarboxylic acid and palladium may more properly form a complex, so that both patternability and electroless plating deposition tend to be better achieved.

The catalyst application bath for electroless plating may contain a buffer to enhance the pH buffering capacity.

Any buffer that has a buffering capacity may be used. Examples of compounds having a buffering capacity at pH 6.5 or less include sodium salts, potassium salts, and ammonium salts of citric acid, tartaric acid, and acetic acid. These may be used alone or in combinations of two or more.

The buffer concentration in the catalyst application bath for electroless plating is preferably 1.0 to 50 g/L, more preferably 5.0 to 30 g/L.

### Other Components

The catalyst application bath for electroless plating may contain, in addition to the above-described components, components that are generally used in catalyst application baths for electroless plating, such as a Cu ion scavenger or a surfactant.

The catalyst application bath for electroless plating of the present invention is suitably usable as a catalyst application bath for electroless plating for a material having a surface on which copper and/or a copper alloy is exposed.

### Method of Producing Catalytic Nucleus-Containing Material to be Electroless Plated (Catalyst Application Method)

The method of producing a catalytic nucleus-containing material to be electroless plated according to the present invention (the method of subjecting a material to be electroless plated to catalyst application according to the present invention) includes catalyst application including allowing a material to be electroless plated to contact the catalyst application bath for electroless plating of the present invention.

The material to be electroless plated may be any material having a surface on which a metal is exposed. Examples include materials made of one or a combination of materials such as plastics such as glass fiber-reinforced epoxies, polyimides, and PET, glass, ceramic, metal oxides, metals, paper, and synthetic or natural fibers. The form of the material may be any of the following: plate, film, fabric, fiber, tube, etc. Examples of the metal exposed on the surface include copper, copper alloys, silver, silver alloys, gold, gold alloys, molybdenum, and tungsten. Among these, applicable copper alloys, silver alloys, and gold alloys contain, for example, at least 50% by mass of copper, silver, and gold, respectively. In particular, the metal exposed on the surface is preferably copper or a copper alloy. Specific examples of the material to be electroless plated include printed wiring boards, semiconductor packages, electronic components, and ceramic substrates. In such a material, the metal exposed on the surface can form traces.

Preferably, the material to be electroless plated has been subjected to pretreatment by a known method, such as cleaner treatment (e.g., degreasing), hot water washing, soft etching, acid cleaning, or pre-dip.

Specific methods for allowing the material to be electroless plated to contact the catalyst application bath for electroless plating of the present invention are not limited. Usually, the target material may be immersed in the catalyst application bath for electroless plating of the present invention. The catalyst application may also be carried out by other methods such as spraying or applying the catalyst application bath to the surface of the material to be electroless plated.

The liquid temperature of the catalyst application bath for electroless plating of the present invention in the catalyst application step is not limited. Usually, it is preferably about 5° C. to about 80° C., more preferably about 15° C. to about 50° C.

The duration of the catalyst application step is not limited. Usually, it is preferably about 5 seconds to about 30 minutes, more preferably about 15 seconds to about 10 minutes.

A palladium-containing catalytic nucleus may be formed on the metal surface of a material to be electroless plated by the method of producing a catalytic nucleus-containing material to be electroless plated according to the present invention (the method of subjecting a material to be electroless plated to catalyst application according to the present invention) . The composition of the catalytic nucleus depends on the components (especially metal components) in the catalyst application bath for electroless plating of the present invention. For example, when the catalyst application bath for electroless plating of the present invention contains a metal element-containing compound, the catalytic nucleus will contain palladium and the metal.

The palladium content of the catalytic nucleus is preferably 80% by mass or higher, more preferably 90% by mass or higher, still more preferably 95% by mass or higher, particularly preferably 98% by mass or higher, and may be 100% by mass. In such cases, both patternability and electroless plating deposition tend to be better achieved.

Herein, the element contents of the catalytic nucleus are measured using an ICP spectrometer (HORIBA).

The catalytic nucleus-containing material to be electroless plated may be electroless plated to form an electroless plating deposit with better patternability, electroless plating deposition, etc. The catalytic nucleus is for surface activation and thus may have a catalyst content of 2 μg/dm² or higher, or 2 to 100 μg/dm², for example.

### Method of Producing Material with Electroless Plating Deposit

The method of producing a material with an electroless plating deposit according to the present invention (the method of electroless plating a material to be electroless plated according to the present invention) includes catalyst application including allowing a material to be electroless plated to contact the catalyst application bath for electroless plating of the present invention; and electroless plating after the catalyst application.

The catalyst application step is the same as that described in the method of producing a catalytic nucleus-containing material to be electroless plated.

In the plating step, the catalytic nucleus-containing material to be electroless plated obtained in the catalyst application step is subjected to electroless plating after the catalyst application step. Specifically, in the plating step, electroless plating is performed by allowing the catalytic nucleus-containing material to be electroless plated obtained in the catalyst application step to contact an electroless plating bath. Thus, a material with an electroless plating deposit is produced.

The electroless plating bath is not limited and may be an autocatalytic electroless plating bath. Examples include an electroless palladium plating bath, an electroless palladium alloy plating bath, an electroless copper plating bath, an electroless copper alloy plating bath, an electroless silver plating bath, an electroless silver alloy plating bath, an electroless nickel plating bath, an electroless nickel alloy plating bath, an electroless cobalt plating bath, an electroless cobalt alloy plating bath, an electroless gold plating bath, and an electroless gold alloy plating bath. The specific compositions of these electroless plating baths are not limited. For example, an autocatalytic electroless plating bath having a known composition with a reducing agent component may be used. The plating conditions may also conform to usual plating conditions according to the type of the plating bath used. Moreover, the plating baths may be combined. Specifically, for example, a plating deposit may be formed using an electroless palladium plating bath, followed by forming a plating deposit using an electroless nickel plating bath.

The electroless plating bath is preferably an electroless palladium plating bath, an electroless palladium alloy plating bath, an electroless nickel plating bath, an electroless nickel alloy plating bath, an electroless cobalt plating bath, or an electroless cobalt alloy plating bath, more preferably an electroless palladium plating bath, an electroless palladium alloy plating bath, an electroless nickel plating bath, or an electroless nickel alloy plating bath.

As described above, the present invention preferably does not include a post-dip step. Specifically, no post-dip step is preferably performed between the catalyst application step and the plating step. In this case, both patternability and electroless plating deposition tend to be better achieved.

Further, the present invention preferably includes a water washing step after the catalyst application step. In this case, the unnecessary palladium outside the traces may be removed, eliminating the need for a conventional post-dip step. As a result, the post-dip step-related problem, i.e., the possibility of non-deposition in electroless plating, is eliminated, resulting in good electroless plating deposition.

The method of producing a material with an electroless plating deposit according to the present invention (the method of electroless plating a material to be electroless plated according to the present invention) may form an electroless plating deposit with better patternability, electroless plating deposition, etc. The method of producing a material with an electroless plating deposit according to the present invention (the method of electroless plating a material to be electroless plated according to the present invention) may provide a material with such an electroless plating deposit, specifically, a material that includes a material having a surface on which a metal is exposed, a catalytic nucleus on the metal, and a deposit on the catalytic nucleus, in which the catalytic nucleus contains palladium, and the deposit is an electroless plating deposit.

The conditions and concentration settings of the processes described above are not limited to those described above. Obviously, they can be appropriately changed depending on the thickness of the deposit to be formed, etc.

The material with an electroless plating deposit provided by the present invention can be used in various electronic components. Examples of the electronic components include electronic components used in home appliances, in-vehicle equipment, power transmission systems, transportation equipment, communication equipment, etc. Specific examples include power modules, power control units, etc. for air conditioners, elevators, electric vehicles, hybrid vehicles, trains, and power generation equipment, general home appliances, and personal computers.

### EXAMPLES

The present invention will be specifically described with reference to examples, but the invention is not limited to these examples.

According to the conditions shown in Tables 4 to 7, substrates with a copper trace width of 50 um and a space between traces of 20 um were subjected to various processes to perform electroless nickel plating (nickel deposit thickness: 4 μm) or electroless palladium plating (palladium deposit thickness: 0.15 μm). The resulting substrates were evaluated for patternability based on the degree of deposition of nickel or palladium in the spaces between the traces.

Here, in the case of electroless nickel plating, the patternability was evaluated as “Good” when the space between the traces was 10 μm or more, “Not acceptable” when the traces were connected, and “Acceptable” when the traces were not connected and the distance between the traces was less than 10 μm, after the electroless nickel plating.

Also, in the case of electroless palladium plating, the patternability was evaluated as “Good” when the space between the traces was 15 μm or more, “Acceptable” when the distance between the traces was 10 to less than 15 μm, and “Not acceptable” when the distance was less than 10 μm, after the electroless palladium plating.

Further, the electroless plating deposition was evaluated as “Good” when electroless nickel or palladium deposition occurred and “Bad” when no deposition occurred. Tables 4 to 7 show the evaluation results.

In Tables 4 to 7, the palladium concentration refers to the concentration calculated as palladium element (mg/L) .

Moreover, the processes in Tables 2 and 3 were carried out from top to bottom.

As shown in Tables 4 to 7, no post-dip step was performed in the Examples.

TABLE 2

| | | | Temperature | Duration |
|---|---|---|---|---|
| Plating step | | | (° C.) | (min) |
| Cleaner | ACL-007, C. Uyemura & | | 50 | 5 |
| | Co., Ltd. | | | |
| Hot water | Warm ion exchange water | | 50 | 1 |
| washing | | | | |
| Soft etching | Sodium persulfate | 100 g/L | 25 | 1 |
| | Sulfuric acid | 20 g/L | | |
| Acid cleaning | Sulfuric acid | 50 g/L | Room | 1 |
| | | | temperature | |

| Pre-dip | see Tables 4 to 6 | Room | 1 |
|---|---|---|---|
| | | temperature | |
| Activator | see Tables 4 to 6 | 30 | 2 |
| Post-dip | WHE-4, C. Uyemura & | Room | 1 |
| | Co., Ltd. | temperature | |
| Electroless | NDF-2, C. Uyemura & | 85 | 20 |
| nickel plating | Co., Ltd. | | |

TABLE 3

| | | | Temperature | Duration |
|---|---|---|---|---|
| Plating step | | | (° C.) | (min) |
| Cleaner | ACL-007, C. Uyemura & | | 50 | 5 |
| | Co., Ltd. | | | |
| Hot water | Warm ion exchange water | | 50 | 1 |
| washing | | | | |
| Soft etching | Sodium persulfate | 100 g/L | 25 | 1 |
| | Sulfuric acid | 20 g/L | | |
| Acid cleaning | Sulfuric acid | 50 g/L | Room | 1 |
| | | | temperature | |

| Pre-dip | see Table 7 | Room | 1 |
|---|---|---|---|
| | | temperature | |
| Activator | see Table 7 | 30 | 2 |
| Post-dip | WSH-34, C. Uyemura & | 50 | 0.5 |
| | Co., Ltd. | | |
| Electroless | TPG-39, C. Uyemura & | 60 | 20 |
| palladium | Co., Ltd. | | |
| plating | | | |

TABLE 4

| Composition of activator bath | | | | | | | | |
|---|---|---|---|---|---|---|---|---|
| Components | Unit | Example 1 | Example 2 | Example 3 | Example 4 | Example 5 | Example 6 | Example 7 |
| Palladium chloride | mg/L | 20 | 20 | 20 | 20 | 20 | 20 | 20 |
| (as palladium) | | | | | | | | |
| Palladium sulfate | mg/L | | | | | | | |
| (as palladium) | | | | | | | | |
| Hydrochloric acid | g/L | 30 | 30 | 30 | 30 | 30 | 30 | 30 |
| Sulfuric acid | g/L | | | | | | | |
| L-methionine | g/L | 2 | | | | | | |
| L-histidine | g/L | | 2 | | | | | |
| L-glutamine | g/L | | | 2 | | | | |
| L-aspartic acid | g/L | | | | 2 | | | |
| L-cysteine | g/L | | | | | 2 | | |
| L-proline | g/L | | | | | | 2 | |
| N-methyl-L-methionine | g/L | | | | | | | 2 |
| N-methyl-L-proline | g/L | | | | | | | |
| L-cysteine ethyl ester | g/L | | | | | | | |
| L-histidine ethyl ester | g/L | | | | | | | |
| N-acetyl-L-methionine | g/L | | | | | | | |
| N-acetyl-L-histidine | g/L | | | | | | | |
| pH | | <1 | <1 | <1 | <1 | <1 | <1 | <1 |
| Temperature | [° C.] | 30 | 30 | 30 | 30 | 30 | 30 | 30 |
| Pre-dip | | Hydrochloric | Hydrochloric | Hydrochloric | Hydrochloric | Hydrochloric | Hydrochloric | Hydrochloric |
| | | acid | acid | acid | acid | acid | acid | acid |
| Post-dip | | No | No | No | No | No | No | No |
| Patternability | Judgement | Good | Good | Good | Good | Good | Good | Good |
| Electroless | | Good | Good | Good | Good | Good | Good | Good |
| nickel deposition | | | | | | | | |

| Composition of activator bath | | | | | | | Example | Example |
|---|---|---|---|---|---|---|---|---|
| Components | Unit | Example 8 | Example 9 | Example 10 | Example 11 | Example 12 | 13 | 14 |
| Palladium chloride | mg/L | 20 | 20 | 20 | 20 | 20 | | |
| (as palladium) | | | | | | | | |
| Palladium sulfate | mg/L | | | | | | 20 | 20 |
| (as palladium) | | | | | | | | |
| Hydrochloric acid | g/L | 30 | 30 | 30 | 30 | 30 | | |
| Sulfuric acid | g/L | | | | | | 30 | 30 |
| L-methionine | g/L | | | | | | 2 | |
| L-histidine | g/L | | | | | | | 2 |
| L-glutamine | g/L | | | | | | | |
| L-aspartic acid | g/L | | | | | | | |
| L-cysteine | g/L | | | | | | | |
| L-proline | g/L | | | | | | | |
| N-methyl-L-methionine | g/L | | | | | | | |
| N-methyl-L-proline | g/L | 2 | | | | | | |
| L-cysteine ethyl ester | g/L | | 2 | | | | | |
| L-histidine ethyl ester | g/L | | | 2 | | | | |
| N-acetyl-L-methionine | g/L | | | | 2 | | | |
| N-acetyl-L-histidine | g/L | | | | | 2 | | |
| pH | | <1 | <1 | <1 | <1 | <1 | <1 | <1 |
| Temperature | [° C.] | 30 | 30 | 30 | 30 | 30 | 30 | 30 |
| Pre-dip | | Hydrochloric | Hydrochloric | Hydrochloric | Hydrochloric | Hydrochloric | Sulfuric | Sulfuric |
| | | acid | acid | acid | acid | acid | acid | acid |
| Post-dip | | No | No | No | No | No | No | No |
| Patternability | Judgement | Good | Good | Good | Good | Good | Good | Good |
| Electroless | | Good | Good | Good | Good | Good | Good | Good |
| nickel deposition | | | | | | | | |

TABLE 5

| Composition of activator bath | | | | | | | | |
|---|---|---|---|---|---|---|---|---|
| Components | Unit | Example 15 | Example 16 | Example 17 | Example 18 | Example 19 | Example 20 | Example 21 |
| Palladium chloride (as palladium) | mg/L | 20 | 20 | 20 | 20 | 20 | 20 | 20 |
| Hydrochloric acid | g/L | 30 | 30 | 30 | 30 | 30 | 30 | 30 |
| L-methionine | g/L | 0.2 | 0.5 | 10 | 20 | 2 | 2 | 2 |
| Ammonia | | | | | | as needed | as needed | as needed |
| | | | | | | for pH | for pH | for pH |
| | | | | | | adjustment | adjustment | adjustment |
| pH | | <1 | <1 | <1 | <1 | 1.5 | 3.5 | 6.5 |
| Temperature | [° C.] | 30 | 30 | 30 | 30 | 30 | 30 | 30 |
| Pre-dip | | Hydrochloric | Hydrochloric | Hydrochloric | Hydrochloric | Hydrochloric | Hydrochloric | Hydrochloric |
| | | acid | acid | acid | acid | acid | acid | acid |
| Post-dip | | No | No | No | No | No | No | No |
| Patternability | Judgement | Acceptable | Good | Good | Good | Good | Good | Good |
| Electroless nickel deposition | | Good | Good | Good | Good | Good | Good | Good |

TABLE 6

| Composition of activator bath | | | | Comparative | Comparative |
|---|---|---|---|---|---|
| Components | Unit | Example 1 | Example 2 | Example 1 | Example 2 |
| Palladium chloride (as palladium) | mg/L | 20 | 20 | 20 | 20 |
| Hydrochloric acid | g/L | 30 | 30 | 30 | 30 |
| L-methionine | g/L | 2 | | | |
| L-histidine | g/L | | 2 | | |
| pH | | <1 | <1 | <1 | <1 |
| Temperature | [° C.] | 30 | 30 | 30 | 30 |
| Pre-dip | | Hydrochloric | Hydrochloric | Hydrochloric | Hydrochloric |
| | | acid | acid | acid | acid |
| Post-dip | | No | No | No | Yes |
| Patternability | Judgement | Good | Good | Not | Not |
| | | | | acceptable | acceptable |
| Electroless nickel deposition | | Good | Good | Good | Good |

TABLE 7

| Composition of activator bath | | | | Comparative | Comparative |
|---|---|---|---|---|---|
| Components | Unit | Example 22 | Example 23 | Example 3 | Example 4 |
| Palladium sulfate (as palladium) | mg/L | 100 | 100 | 100 | 100 |
| Sulfuric acid | g/L | 30 | 30 | 30 | 30 |
| L-methionine | g/L | 2 | | | |
| L-histidine | g/L | | 2 | | |
| pH | | <1 | <1 | <1 | <1 |
| Temperature | [° C.] | 30 | 30 | 30 | 30 |
| Pre-dip | | Sulfuric acid | Sulfuric acid | Sulfuric acid | Sulfuric acid |
| Post-dip | | No | No | No | Yes |
| Patternability | Judgement | Good | Good | Not | Acceptable |
| | | | | acceptable | |
| Electroless palladium deposition | | Good | Good | Good | Good |

Tables 2 to 7 show that the catalyst application baths for electroless plating of the Examples each containing a palladium compound and an aminocarboxylic acid may provide good patternability even without a post-dip step which can cause non-deposition in electroless plating, and thus may achieve both patternability and electroless plating deposition.

1. A catalyst application bath for electroless plating, comprising
at least one palladium compound and
at least one aminocarboxylic acid.

2. The catalyst application bath for electroless plating according to claim 1,
wherein the catalyst application bath comprises the palladium compound in an amount corresponding to a palladium concentration of 1 to 1000 mg/L.

3. The catalyst application bath for electroless plating according to claim 1,
wherein the catalyst application bath comprises the aminocarboxylic acid in an amount of 0.2 to 20 g/L.

4. The catalyst application bath for electroless plating according to claim 1,
wherein the catalyst application bath comprises an inorganic acid.

5. The catalyst application bath for electroless plating according to claim 1,
wherein the catalyst application bath has a pH of 6.5 or less.

6. The catalyst application bath for electroless plating according to claim 1,
wherein the electroless plating is for a material having a surface on which at least one of copper or a copper alloy is exposed.

7. A method of producing a catalytic nucleus- containing material to be electroless plated, the method comprising
catalyst application comprising allowing a material to be electroless plated to contact the catalyst application bath for electroless plating according to claim 1.

8. A method of producing a material with an electroless plating deposit, the method comprising:
catalyst application comprising allowing a material to be electroless plated to contact the catalyst application bath for electroless plating according to claim 1; and
electroless plating after the catalyst application.

9. A material, comprising:
a material having a surface on which a metal is exposed;
a catalytic nucleus on the metal; and
a deposit on the catalytic nucleus,
the catalytic nucleus comprising palladium,
the deposit being an electroless plating deposit.
